(19) United States
(12) Patent Application Publication
(10) Pub. No.: US 2009/0242127 A1
(43) Pub. Date: Oct. 1, 2009

(54) PLASMA ETCHING APPARATUS AND METHOD, AND COMPUTER-READABLE STORAGE MEDIUM

(75) Inventors: Chishio KOSHIMIZU, Nirasaki City (JP); Manabu IWATA, Nirasaki City (JP); Masanobu HONDA, Nirasaki City (JP); Hiroyuki NAKAYAMA, Nirasaki City (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/411,001

(22) Filed: Mar. 25, 2009

(30) Foreign Application Priority Data
Mar. 28, 2008 (JP) 2008-086861

(51) Int. Cl. H01L 21/306

(52) U.S. Cl. 156/345.28; 156/345.47; 156/345.24

(57) ABSTRACT

A plasma etching apparatus includes a processing vessel; a lower electrode on which a target substrate is mounted in the processing vessel; an upper electrode disposed in the processing vessel to face the lower electrode in parallel; a processing gas supply unit configured to supply a processing gas into a processing space between the upper and the lower electrode; a first radio frequency power supply unit configured to apply, to the lower electrode, a first radio frequency power for generating plasma of the processing gas; a focus ring covering a top surface peripheral portion of the lower electrode protruding toward a radial outside of the substrate; a DC power supply configured to output a variable DC voltage; and a DC voltage supply network that connects the DC power supply to either one of the focus ring and the upper electrode or both depending on processing conditions of plasma etching.

### FIELD OF THE INVENTION

The present invention relates to a capacitively coupled plasma etching apparatus for performing a dry etching process on a target substrate by using plasma; a plasma etching method; and a computer-readable storage medium.

### BACKGROUND OF THE INVENTION

Etching, which is employed in a manufacturing process of a semiconductor device or a FPD (Flat Panel Display), is a technique for processing a film on the surface of a target substrate (a semiconductor wafer, a glass substrate, or the like) into a desired circuit pattern by using a resist pattern, which is formed by a lithography technique, as a mask. Conventionally, a capacitively coupled plasma etching apparatus has been a mainstream of single-wafer etching apparatuses.

Generally, the capacitively coupled plasma etching apparatus has a configuration in which an upper electrode and a lower electrode are disposed in parallel to each other in a processing vessel configured as a vacuum chamber. In this configuration, the target substrate is disposed on the lower electrode, and a radio frequency power is applied between the two electrodes, whereby electrons accelerated by a high frequency electric field formed between the two electrodes, electrons released from the electrodes or heated electrons are made to collide with and ionize molecules of a processing gas. As a result, plasma of the processing gas is generated, and a desired micro-processing, e.g., an etching process, is performed on the surface of the substrate by radicals or ions in the plasma.

Here, since the electrode to which the radio frequency power is applied is connected with a radio frequency power supply via a blocking capacitor within a matching unit, the electrode functions as a cathode. In a cathode couple type apparatus in which the radio frequency power is applied to the lower electrode mounting the substrate thereon so that the lower electrode is allowed to function as the cathode, ions in the plasma are attracted toward the substrate substantially in a vertical manner by using a self-bias voltage generated on the lower electrode, so that anisotropic etching having a high directionally is enabled (see, for example, Japanese Patent Application Publication No. H6-283474 and U.S. Pat. No. 5,494,522).

Recently, a lower-side dual frequency application type is also widely employed wherein a first radio frequency power having a relatively high frequency level (typically, no smaller than about 40 MHz) suitable for plasma generation (high frequency discharge) and a second radio frequency power having a relatively low frequency level (typically, no greater than about 13.56 MHz) are applied to the lower electrode at the same time (see, for example, Japanese Patent Application Publication No. 2007-266529).

Furthermore, in the capacitively coupled plasma etching apparatus, there is also proposed applying a DC voltage to the upper electrode facing the substrate through the plasma while generating the plasma between the upper and the lower electrode by the above-stated high frequency discharge (hereinafter, referred to as an “upper-side DC application type” (see, for example, Japanese Patent Application Publication No. 2006-270019 and U.S. Patent Application Publication No. 2006/0066247 A1). According to the upper-side DC application method, there can be obtained at least one of such effects (basic effects) as (1) enhancing sputtering (elimination of deposits) on the upper electrode by increasing the absolute value of a self-bias voltage of the upper electrode; (2) downscaling the formed plasma by enlarging a plasma sheath on the upper electrode; (3) irradiating electrons generated in the vicinity of the upper electrode onto the target substrate; (4) enabling a control of a plasma potential; (5) increasing an electron density (plasma density); and (6) increasing a plasma density in a central portion. In the etching process, plasma ignition stability, resist selectivity and improvement of etching rate and etching uniformity (process characteristic effects) are expected to be obtained based on the above-stated basic effects.

Meanwhile, an organic film is often provided between a processing target film and a resist on the substrate as a lower resist in a multilayer resist method or as an anti-reflection film for reducing a standing wave generated during a patterning exposure process. In such case, in the same plasma etching apparatus, the organic film is first etched by using the uppermost resist as a mask, and then the processing target film is etched by using the resist and the organic film as a mask.

In the plasma etching of the organic film, however, though also affected by an employed gas or pressure, an etching rate at a central portion on the substrate generally becomes much smaller than an etching rate at a periphery portion when it is attempted to obtain a desired or optimal etching characteristic. As a result, in-plane etching uniformity cannot be obtained, and it is known that this problem cannot be completely resolved only by the above-described upper-side DC application method.

As a solution to this problem, it may be considered to invent better design for the electrode structure or gas supply system so as to lower the etching rate of the substrate periphery portion by relatively increasing the etching rate of the substrate central portion. However, such approach not only causes a scale-up of hardware but also causes another (even worse) problem that the in-planed uniformity cannot be maintained because the etching rate of the substrate central portion becomes excessively higher than the etching rate of the substrate periphery portion when etching the processing target film. Thus, this solution has no practical use.

### SUMMARY OF THE INVENTION

In view of the foregoing, the present invention provides a plasma etching apparatus capable of simply and effectively correcting or solving the problem of an unintended decrease of an etching rate of a central portion of the substrate lower than that of a periphery portion.

The present invention also provides a plasma etching apparatus capable of easily improving characteristics or in-plane uniformity of the etching of an organic film without the expense of deteriorating characteristics or in-plane uniformity of the etching of a non-organic film under the same hardware.

Further, the present invention also provides a plasma etching method capable of easily and efficiently improving in-plane uniformity of etching rate on a target substrate in the etching of an organic film, and also provides a computer readable storage medium to be used therein.

In accordance with a first aspect of the present invention, there is provided a plasma etching apparatus comprising: a processing vessel which is evacuatable to vacuum; a lower electrode on which a target substrate is mounted in the processing vessel; an upper electrode disposed in the processing vessel to face the lower electrode in parallel thereto; a processing gas supply unit configured to supply a processing gas into a processing space between the upper electrode and the lower electrode; a first radio frequency power supply unit configured to apply, to the lower electrode, a first radio frequency power for generating plasma of the processing gas by a high frequency discharge; a focus ring covering a top surface peripheral portion of the lower electrode protruding toward a radial outside of the substrate; a DC power supply configured to output a variable DC voltage; and a DC voltage supply network (lines) that connects the DC power supply to either one of the focus ring and the upper electrode or both depending on processing conditions of plasma etching.

In the above-stated configuration, by applying the DC voltage to the focus ring via the DC voltage supply network after selecting a proper voltage value (absolute value) and polarity of the DC voltage, a balance between an electric current emitted into the processing space from a substrate mounting portion or the substrate on the lower electrode and an electric current emitted from the focus ring can be adjusted, and an in-plane distribution characteristic of etching rate can be controlled. Further, by applying the DC voltage of the proper voltage value (absolute value) and polarity to the upper electrode from the DC power supply via the DC voltage supply network, basic effects or process characteristic effects of a so-called upper-side DC application method can be obtained.

Desirably, by providing a DC ground electrode at a position exposed to the plasma in the processing vessel and DC-ground it, a DC current may be flown between the DC ground electrode and the upper electrode or the focus ring through the plasma. With this configuration, an abnormal discharge can be prevented from occurring in the upper electrode or the focus ring.

In accordance with a second aspect of the present invention, there is provided a plasma etching apparatus comprising: a processing vessel which is evacuatable to vacuum; a lower electrode on which a target substrate is mounted in the processing vessel; an upper electrode disposed in the processing vessel to face the lower electrode in parallel thereto; a processing gas supply unit configured to supply a processing gas into a processing space between the upper electrode and the lower electrode; a first radio frequency power supply unit configured to apply, to the lower electrode, a first radio frequency power for generating plasma of the processing gas by a high frequency discharge; a focus ring covering a top surface peripheral portion of the lower electrode protruding toward a radial outside of the substrate, a first DC power supply configured to output a first variable DC voltage to be applied to the upper electrode; a second DC power supply configured to output a second variable DC voltage to be applied to the focus ring; and a DC voltage supply network (lines) that connects the first and second DC power supplies to the upper electrode and the focus ring respectively, or connects either one of the first and second power supplies to the upper electrode or the focus ring depending on processing conditions of plasma etching.

In the above-stated configuration, by providing the first and second DC power supplies, the individual DC voltages can be applied to the upper electrode and the focus ring independently, so that the effect of optimizing the double effects of the upper-side DC application method and a focus-ring DC application method can be obtained in addition to the operation and effect obtainable by the first aspect of the present invention.

In accordance with a third aspect of the present invention, there is provided a plasma etching apparatus comprising: a processing vessel which is evacuatable to vacuum; a lower electrode on which a target substrate is mounted in the processing vessel; an upper electrode disposed in the processing vessel to face the lower electrode in parallel thereto; a processing gas supply unit configured to supply a processing gas into a processing space between the upper electrode and the lower electrode; a first radio frequency power supply unit configured to apply, to the lower electrode, a first radio frequency power for generating plasma of the processing gas by a high frequency discharge; a focus ring covering a top surface peripheral portion of the lower electrode protruding toward a radial outside of the substrate; a DC power supply configured to output a variable DC voltage; a DC ground electrode provided at a position exposed to the plasma in the processing vessel and DC-grounded to flow a DC current between the DC ground electrode and the upper electrode or the focus ring through the plasma; a DC voltage supply network (lines) that connects the DC power supply to either one of the focus ring and the upper electrode or both depending on processing conditions and grounds the DC ground electrode when etching a processing target film on the substrate, and connects the DC power supply with the DC ground electrode and grounds at least one of the upper electrode and the focus ring when sputter-cleaning the surface of the DC ground electrode.

In the above-stated configuration, sputter-cleaning for removing deposits adhered on the surface of the DC ground electrode can be performed in addition to achieving the operation and effect obtainable by the first aspect of the present invention as well. Besides, in the sputter-cleaning, the focus ring can be employed as a ground member instead of the upper electrode.

In accordance with another aspect of the present invention, there is also provided a second radio frequency power supply unit for applying a second radio frequency power mainly for attracting ions in the plasma onto the substrate on the lower electrode. The second radio frequency power supply unit may be selectively used depending on processing conditions.

In accordance with another aspect of the present invention, there is provided a plasma etching method for etching at least an organic film on the substrate by using the plasma etching apparatus of the above, wherein, in a process of etching the organic film, a negative DC voltage having an absolute value larger than that of a self-bias voltage generated on the lower electrode is applied to the focus ring.

As described, in the etching process of the organic film, by applying the negative DC voltage, which has the absolute value larger than that of the self-bias voltage generated on the lower electrode, to the focus ring, the etching rate of a substrate central portion on the substrate can be increased by lowering the etching rate of a substrate edge portion relatively.

The plasma etching of the present invention can be appropriately applied to radical-based etching of an organic film, and, particularly, can be applied to an etching process using a processing gas such as an O₂ gas, a N₂ gas or the like without containing an inert gas.

It is preferable that the organic film is a carbon film and the processing gas is an O₂ gas.

It is preferable that a processing target film is formed on the substrate in addition to the organic film, and no DC voltage is applied to the focus ring in an etching process of the processing target film.

It is preferable that a specified DC voltage is selectively applied to the upper electrode depending on processing conditions.

In accordance with a fourth aspect of the present invention, there is provided a computer readable storage medium that stores a computer executable control program, wherein, when executed, the control program controls the plasma etching apparatus to carry out the plasma etching method of the above.

In accordance with the plasma etching apparatus of the present invention, the problem of an unintended decrease of an etching rate of a central portion of the substrate to a lower level than that of a periphery portion can be solved or corrected simply and effectively. Moreover, characteristics or in-plane uniformity of the etching of the organic film can be improved easily without the expense of deteriorating characteristics or in-plane uniformity of the etching of a non-organic film under the same hardware.

Further, in accordance with the plasma etching method and the computer readable storage medium of the present invention, it is possible to easily and efficiently improve in-plane uniformity of etching rate on the substrate in the etching of the organic film.

### BRIEF DESCRIPTION OF THE DRAWINGS

The above and other objects and features of the present invention will become apparent from the following description of embodiments given in conjunction with the accompanying drawings, in which:

FIG. 1 is a longitudinal cross sectional view illustrating a configuration of a capacitively coupled plasma etching apparatus in accordance with an embodiment of the present invention;

FIG. 2 sets forth a diagram for describing an operation in case that a preset DC voltage is applied to a focus ring in accordance with the embodiment of the present invention;

FIG. 3 depicts a diagram for describing an operation of an electron current flowing in a wafer mounting portion of a susceptor when the preset DC voltage is applied to the focus ring in accordance with the embodiment of the present invention;

FIG. 4 offers a diagram for describing an operation of an electron current flowing in the focus ring when the preset DC voltage is applied to the focus ring in accordance with the embodiment of the present invention;

FIG. 5 presents a chart showing an in-plane distribution characteristic of etching rates when an organic film is etched in accordance with the embodiment of the present invention;

FIG. 6 provides a diagram for describing an operation in case that a preset DC voltage is applied to an upper electrode in accordance with the embodiment of the present invention;

FIG. 7 shows a configuration example of DC voltage supply mechanisms respectively provided at the upper electrode and the focus ring in accordance with the embodiment of the present invention;

FIGS. 8A to 8C are diagrams for illustrating a typical process for etching an organic film on a semiconductor wafer W in accordance with the embodiment of the present invention;

FIG. 9 is a longitudinal cross sectional view of a capacitively coupled plasma etching apparatus in accordance with another embodiment of the present invention; and

FIG. 10 presents a block diagram illustrating a configuration example of a control unit in accordance with the embodiment of the present invention.

### DETAILED DESCRIPTION OF THE EMBODIMENTS

Hereinafter, embodiments of the present invention will be described with reference to the accompanying drawings.

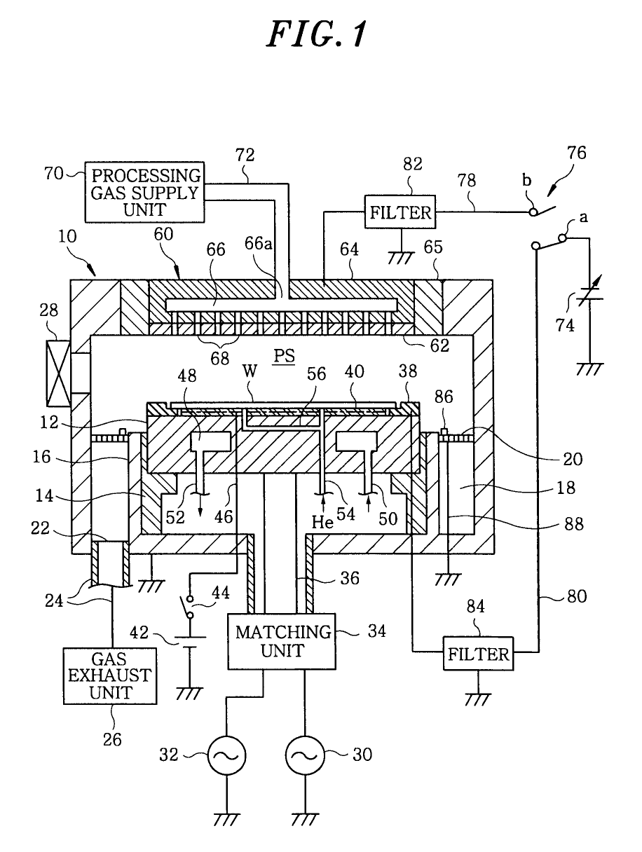

FIG. 1 illustrates a configuration of a plasma etching apparatus in accordance with a first embodiment of the present invention. The plasma etching apparatus is configured as a capacitively coupled plasma etching apparatus of a cathode-coupled type employing a lower-side dual frequency application mechanism. The plasma etching apparatus includes a cylindrical chamber (processing vessel) 10 made of a metal such as aluminum, stainless steel, or the like. The chamber 10 is frame-grounded.

A circular plate-shaped susceptor 12 for mounting, for example, a semiconductor wafer W thereon is horizontally installed in the chamber 10 to be used as a lower electrode. The susceptor 12 is made of, for example, aluminum and is supported on an insulating cylindrical support 14 extended vertically upward from the bottom of the chamber 10. An annularly shaped gas exhaust path 18 is formed between a sidewall of the chamber 10 and a conductive cylindrical support (inner wall portion) 16 extended vertically upward from the bottom of the chamber 10 along the outer periphery of the cylindrical support 14. A ring-shaped baffle plate (gas exhaust ring) 20 is attached to the inlet of the gas exhaust path 18, and a gas exhaust port 22 is formed at the bottom of the gas exhaust path 88. A gas exhaust unit 26 is connected with the gas exhaust port 22 via a gas exhaust pipe 24. The gas exhaust unit 26 includes a vacuum pump such as a turbo molecular pump or the like and is capable of depressurizing a processing space inside the chamber 10 to a desired vacuum level. A gate valve 28 for opening or closing a loading/unloading port of the semiconductor wafer W is provided at the sidewall of the chamber 10.

A first and a second radio frequency power supply 30 and 32 are electrically connected with the susceptor 12 via a matching unit 34 and a power supply rod 36. Here, the first radio frequency power supply 30 outputs a first radio frequency power of a preset frequency level, e.g., about 40 MHz, which mainly contributes to plasma generation, while the second radio frequency power supply 32 outputs a second radio frequency power of a certain frequency level, e.g., about 2 MHz, which mainly contributes to ion attraction toward the semiconductor wafer W on the susceptor 12. The matching unit 34 includes a first matching device for matching an impedance on the side of the first frequency power supply 30 and an impedance on a load side (mainly electrode, plasma, chamber) and a second matching device for matching an impedance on the side of the second radio frequency power supply 32 and the load-side impedance.

The susceptor 12 has a larger diameter than the semiconductor wafer W. The semiconductor wafer W mounted on the top surface of the susceptor 12A, and a focus ring (calibration ring) 38 is disposed to surround the mounted semiconductor wafer W. The focus ring 38 is formed of a conductive material such as Si, SiC, or the like having less influence on a process, and is detachably installed on the top surface of the susceptor 12 as a consumable.

An electrostatic chuck 40 for attracting the wafer is disposed on the top surface of the susceptor 12. The electrostatic chuck 40 includes a sheet-shaped or mesh-shaped conductor embedded in a film-shaped or plate-shaped dielectric. The conductor is connected via a switch 44 and a power supply line 46 to a DC power supply 42 which is disposed outside the chamber 10. The semiconductor wafer W can be attracted to and maintained on the electrostatic chuck 40 by a Coulomb force generated by a DC voltage applied from the DC power supply 42.

Formed inside the susceptor 12 is an annularly shaped coolant reservoir 48 extending along a circumferential direction of the susceptor 12. A coolant of a preset temperature, e.g., cooling water, is supplied into and circulated through the coolant chamber 48 from a chiller unit (not shown) via pipes 50 and 52. Thus, the temperature of the semiconductor wafer W on the electrostatic chuck 40 can be controlled by adjusting the temperature of the coolant. In addition, to further improve the accuracy of the wafer temperature, a thermally conductive gas, e.g., a He gas, is supplied between the electrostatic chuck 40 and the semiconductor wafer W from a thermally conductive gas supply unit (not shown) via a gas supply pipe 54 and a gas passage 56 inside the susceptor 12.

A shower head 60 also serving as an upper electrode is disposed at the ceiling of the chamber 10, facing the susceptor 12 in parallel. The shower head 60 includes an electrode plate 62 facing the susceptor 12 and an electrode support 64 detachably supporting the electrode plate 62 from behind (above) it. A gas diffusion space 66 is provided inside the electrode support 64, and a plurality of gas injection openings 68 is formed through the electrode support 64 and the electrode plate 62 from the gas diffusion chamber 66 toward the susceptor 12 side. A space between the electrode plate 62 and the susceptor 12 becomes a plasma generation space or a processing space PS. A gas inlet port 66a provided at a top portion of the gas diffusion space 66 is connected with a gas supply pipe 72 from a processing gas supply unit 70. Further, the electrode plate 62 is made of, e.g., Si or SiC, and the electrode support 64 is formed of, e.g., alumite-treated aluminum. A ring-shaped insulator 65 is interposed between the shower head (upper electrode) 60 and the chamber 10, whereby the shower (upper electrode) 60 is fastened to the chamber 10 in an electrically floating state.

Disposed outside the chamber 10 is a variable DC power supply 74 capable of outputting a DC voltage capable of being varied in the range of, e.g., about −2000 to +10000 V. An output terminal of the variable DC power supply 74 is capable of being connected with the upper electrode 60 via a changeover switch 76 and a DC power supply line 78 and is also capable of being connected with the focus ring 38 via the changeover switch 76 and a DC power supply line 80. The changeover switch 76 has a fixed contact point a on the side of the variable DC power supply 74; a movable contact point b on the side of the upper electrode 60; and a movable contact point c on the side of the focus ring 38. The movable contact points b and c can be opened or closed independently. With this configuration, the DC voltage outputted from the variable DC power supply 74 can be selectively applied not only to either one of the upper electrode 60 and the focus ring 38 but also both of them. In this embodiment, the changeover switch 76 and the DC power supply lines 78 and 80 constitute a DC voltage supply network.

Filter circuits 82 and 84 are installed on the DC power supply lines 78 and 80, respectively. The filter circuit 82 serves to pass the DC voltage from the variable DC power supply 74 to the upper electrode 60, while allowing a radio frequency power entering the DC power supply line 78 from the susceptor 12 through the processing space PS and the upper electrode 60 to flow to a ground line without letting it flow to the variable DC power supply 74. The filter circuit 84 serves to pass the DC voltage from the variable DC power supply 74 to the focus ring 38, while making a radio frequency power entering the DC power supply line 80 from the susceptor 12 through the focus ring 38 flow to a ground line without allowing it to flow to the variable DC power supply 74.

A DC ground component (DC ground electrode) 86 made of a conductive member such as Si, SiC, or the like is disposed at a proper number of positions facing the processing space PS inside the chamber 10, for example, on the top surface of the baffle plate 20, in the vicinity of the top portion of the support 16, or at a location radially outward of the upper electrode 60. The DC ground component 86 is grounded all the time via a ground line 88.

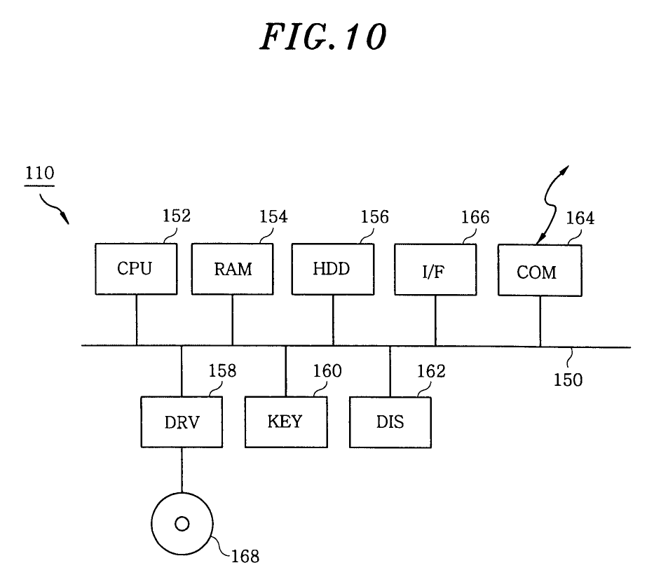

The operation of each component in the plasma etching apparatus, e.g., the gas exhaust unit 26, the radio frequency power supplies 30 and 32, the on/off switch 44, the processing gas supply unit 70, the variable DC power supply 74, the changeover switch 76, the chiller unit (not shown), the thermally conductive gas supply unit (not shown), and so forth and the entire operation (sequence) of the apparatus are controlled by a control unit 110 (see FIG. 10) having a microcomputer therein and operated based on software (program).

To perform an etching process in the plasma etching apparatus configured as described above, a gate valve 28 is first opened and a semiconductor wafer W to be processed is loaded into the chamber 10 and mounted on the electrostatic chuck 40. Then, an etching gas (generally a gaseous mixture) is introduced from the processing gas supply unit 70 into the chamber 10 at a preset flow rate, and the internal pressure of the chamber 10 is controlled to a set value by the gas exhaust unit 26. Further, the first and second radio frequency power supplies 30 and 32 are turned on, and a first radio frequency power of about 40 MHz and a second frequency wave of about 2 MHz are outputted at preset power levels and applied to the susceptor 12 via the matching unit 34 and the power supply rod 36. Further, the switch 44 is turned on, and a thermally conductive gas (He gas) is confined in a contact interface between the electrostatic chuck 40 and the semiconductor wafer W. The etching gas 60 discharged from the shower head 60 is excited into plasma by a high frequency discharge between the two electrodes 12 and 60, and a processing target surface on the semiconductor wafer W is etched into a desired pattern by radicals or ions in the plasma.

The above-described capacitively coupled plasma etching apparatus is capable of generating high-density plasma in a desirable dissociation state under a lower pressure condition by means of applying the first radio frequency power of a relatively high frequency level of about 40 MHz suitable for the plasma generation to the susceptor 12.

At the same time, by applying the second radio frequency power of a relatively low frequency level of about 2 MHz suitable for the ion attraction to the susceptor 12, anisotropic etching can be performed with featuring a high selectivity for the processing target film of the semiconductor wafer W. Here, it is to be noted that the second radio frequency power for the ion attraction may not be used depending on a target process, though the first frequency wave for the plasma generation is inevitably used regardless of the type of the plasma process concerned.

The major characteristic of the above-described capacitively coupled plasma etching apparatus resides in its configuration that is capable of applying the DC voltage outputted from the variable DC power supply 74 to either one of the upper electrode 60 and 38 or both of them via the DC voltage power supply network (i.e., the changeover switch 76 and the DC power supply lines 78 and 80).

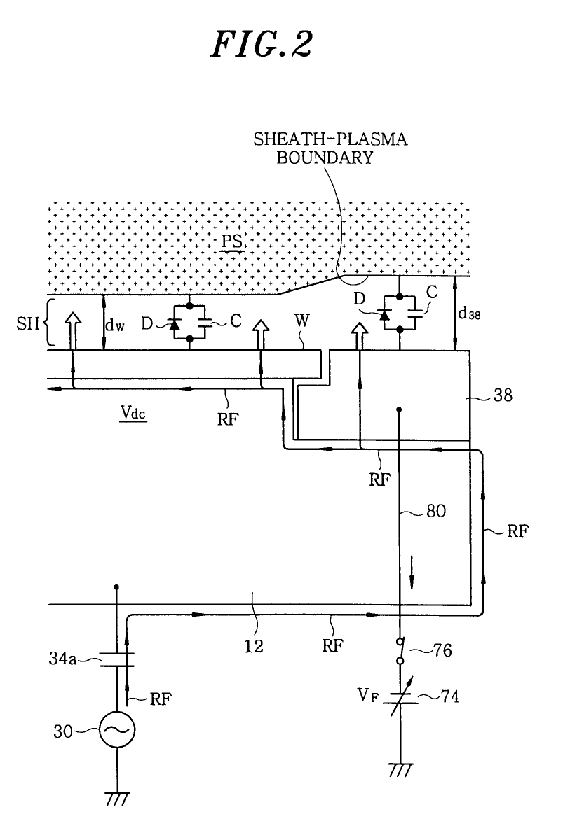

Now, an operation in case that the variable DC power supply 74 is connected to the focus ring 38 will be explained with reference to FIG. 2. In the figure, illustration of the second radio frequency power supply 32 is omitted because the ion attraction by the second radio frequency power is not particularly relevant to the feature of the present invention.

In FIG. 2, the first radio frequency power RF outputted from the first radio frequency power supply 30 flows via the matching unit 34 (specifically, the blocking capacitor 34a within the unit 34), and then enters a bottom surface central portion of the susceptor 12 after flowing up the outer peripheral surface of the power supply rod 36. From there, the first radio frequency power RF radially propagates outward of the susceptor while flowing along a bottom surface layer of the susceptor, and then reaches the top surface of the susceptor after flowing round the outer peripheral surface of the susceptor. On the top surface of the susceptor 12, the first radio frequency power RF propagates radially inward, i.e., from the peripheral portion to the central portion of the susceptor, during which the first radio frequency power RF is emitted into the processing space PS through the focus ring 38 or the semiconductor wafer W and collides with molecules of the processing gas, thus ionizing or decomposing the gas molecules. If plasma is generated in the processing space PS in this way, the plasma is diffused all around the processing space PS, and an ion sheath SH is formed at an interface between the plasma and an object in contact with the plasma. Further, a self-bias voltage V_{dc} having a negative polarity is generated in the susceptor 12 or the focus ring 38 and in the wafer W in a size dependent on the amplitude of the first radio frequency power RF.

As shown in FIG. 2, an equivalent circuit of the ion sheath SH can be expressed by a parallel circuit between a diode D and a capacitor C. Here, the diode D indicates a state in which an electron current flows from the plasma to an electrode side (susceptor 12 and the focus ring 38) at the moment when a potential on the electrode side becomes almost equivalent to a plasma potential within each cycle of the first radio frequency power RF. Further, the capacitor C indicates a state in which a charge density in the surface of the electrode or an electric flux within the ion sheath SH changes with the lapse of time based on a temporal change of a RF voltage within each cycle of the first radio frequency power RF, that is, a flow state of a displacement current.

Further, though a state of inflow of positive ions into the electrode side from the plasma may be indicated by a resistor, it is omitted herein.

In the present embodiment, depending on processing conditions, especially when performing the etching of the organic film, the DC voltage V_{F} outputted from the variable DC power supply 74 is set to have a negative polarity and an absolute value larger than the absolute value of the self-bias voltage V_{dc}, and such DC voltage V_{F} is applied to the focus ring 38 via the changeover switch 76 and the DC power supply line 80.

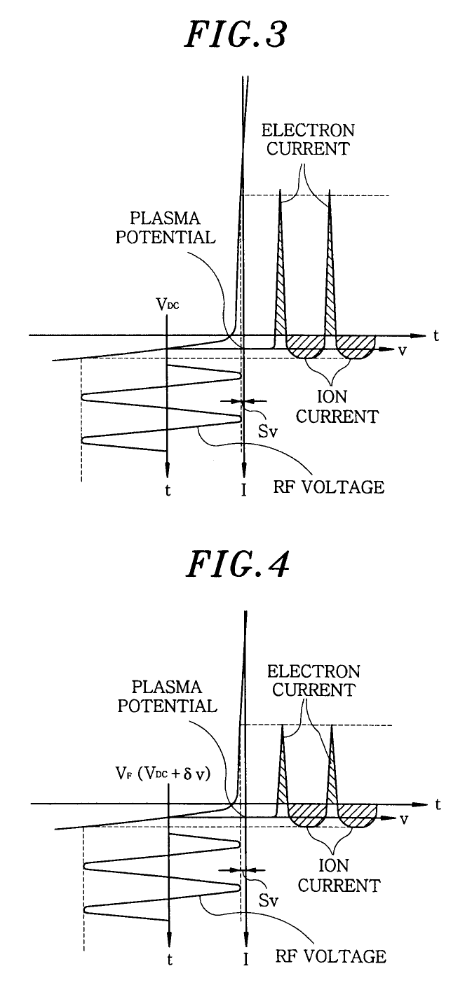

Here, an effect on an electron current, in case that the negative DC voltage V_{F} having the absolute value larger than that of the self-bias voltage V_{dc} is applied to the focus ring 38, will be explained with reference to FIGS. 3 and 4.

FIG. 3 shows a relationship between a voltage (RF voltage) of the first radio frequency power RF applied to the susceptor 12 and an electron current flowing on the wafer mounting portion of the susceptor 12 and a diode D directly above it. At the wafer mounting portion, the RF voltage is overlapped with the self-bias voltage V_{dc}, and when the RF voltage increases up to a peak value of a positive polarity within each RF cycle, the overlapped voltage, i.e., the potential of the wafer mounting portion increases to the extent that a difference Sᵥ between the potential of the wafer mounting portion and the plasma potential almost disappears, so that a great amount of electron current flows into the wafer mounting portion. While the electron current is blocked, an ion current from the plasma flows into the wafer mounting portion, and the electron current and the ion current are canceled (neutralized) within each RF cycle.

FIG. 4 shows a relationship between a voltage (RF voltage) of the first radio frequency power RF applied to the susceptor 12 and an electron current flowing on the focus ring 38 and a diode D directly above it. At the focus ring 39, the RF voltage is overlapped with the DC voltage V_{F}. Here, there is established a relationship of V_{F}=V_{dc}+δV as absolute values. When the RF voltage increases up to a peak value of a positive polarity within each RF cycle, since the overlapped voltage, i.e., the potential of the focus ring 38 is lower than the potential of the wafer mounting portion by as much as δV, the potential difference Sᵥ increases, and the amount of the electron current flowing into the focus ring 38 from the plasma decreases. In such case, the electron current and the ion current are not cancelled (neutralized) within each RF cycle, and the amount of the ion current becomes greater than the amount of the electron current. The extra ion current i flows toward the DC power supply 74 via the DC power supply line 80 and the changeover switch 76.

As described, by applying the negative DC voltage V_{F} of which absolute value is larger than that of the self-bias voltage V_{dc} by δV to the focus ring 38, the electron current emitted into the processing space PS from the focus ring 38 can be suppressed in comparison with the electron current emitted into the processing space PS from the wafer mounting portion of the susceptor 12 or the semiconductor wafer W. Here, as the excess voltage δV of the absolute value is set to be larger, the effect of suppressing the electron current on the focus ring 38 can be more enhanced.

Meanwhile, by applying the negative DC voltage V_{F} having the absolute value larger than that of the self-bias voltage V_{dc} to the focus ring 38, the thickness of the ion sheath SH formed directly above the focus ring 38, that is, an inter-electrode distance d₃₈ of a capacitor C becomes larger than the thickness of the ion sheath SH formed directly above the wafer mounting portion of the susceptor 12 or the semiconductor wafer W, i.e., an inter-electrode distance d_{w} of a capacitor C. Accordingly, the amount of a displacement current flowing between the focus ring 38 and the plasma becomes smaller than that of a displacement current flowing between the wafer mounting portion or the semiconductor wafer W and the plasma, and such difference can be increased by increasing the excess voltage δV.

As described above, by applying the negative DC voltage V_{F} having the absolute value larger than that of the self-bias voltage V_{dc} to the focus ring 38 from the variable DC power supply 74 via the changeover switch 76 and the DC power supply line 80 while controlling the excess voltage δV, the currents (electron current and displacement current) emitted into the processing space PS from the focus ring 38 can be suppressed or reduced to a certain desired level in comparison with the currents (electron current and displacement current) from the wafer mounting portion of the susceptor 12 or the semiconductor wafer W.

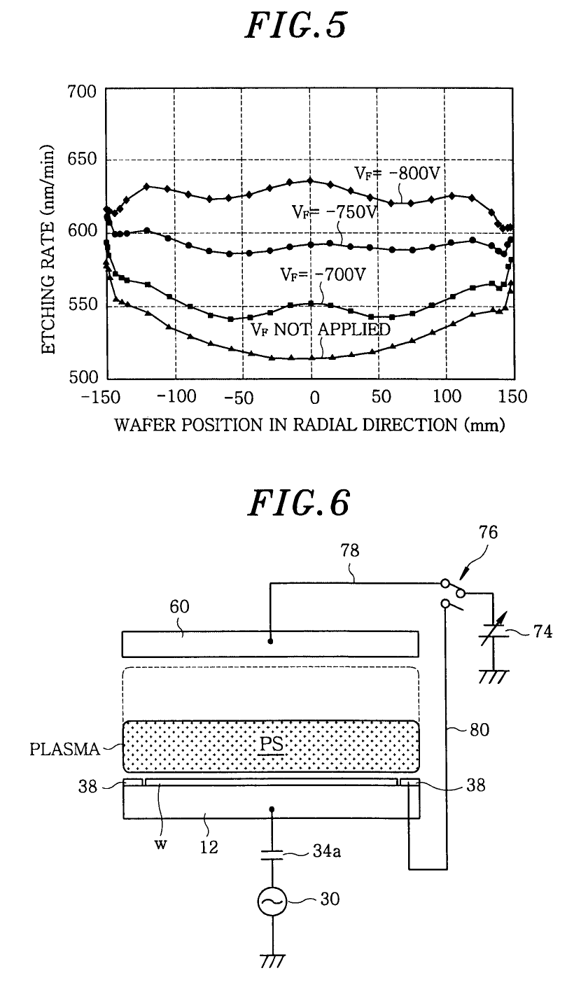

FIG. 5 shows the experiment result of etching an organic film by using the plasma etching apparatus (see FIG. 1) in accordance with the embodiment of the present invention. That is, FIG. 5 shows an example wafer in-plane distribution characteristic of etching rate (E/R). Major conditions for the etching were as follows.
Wafer diameter: 300 mm
Organic film: carbon mask
Processing gas; O₂
Chamber internal pressure:
Radio frequency powers: 40 MHz/2 MHz=500/0 W
Temperature: upper electrode/chamber sidewall/lower electrode=150/150/30° C.
Self-bias voltage: V_{dc}=−650 V
DC voltage: V_{F}=not applied, −700 V, −750 V, −800 V (four cases)

As can be seen from FIG. 5, when no DC voltage V_{F} is applied to the focus ring 38, the etching rate of a wafer central portion is much smaller than the etching rate of a wafer peripheral portion. However, if a negative DC voltage V_{F} having a larger absolute value than a self-bias voltage V_{dc} (−650 V) is applied to the focus ring 38, it is found out that the wafer in-plane distribution characteristic of the etching rate can be greatly improved. That is, if the V_{F} is set to be −700 V, the decrease of the etching rate of the wafer central portion diminishes, and if the V_{F} is set to be −750 V, the difference between the etching rates of the wafer central portion and the wafer peripheral portion becomes minute, so that the in-plane uniformity of the etching rate improves. However, if the V_{F} is set to be −800 V, the etching rate of the wafer central portion becomes rather higher than that of the wafer peripheral portion, resulting in deterioration of the in-plane uniformity again.

As stated above, by varying the absolute value of the DC voltage V_{F}, the etching rate in-plane distribution characteristic or profile in the etching of the organic film can be controlled in a desired way and in-plane uniformity can be easily achieved in the etching of the organic film.

Further, in the etching of the organic film in the example of FIG. 5, no DC voltage is applied to the upper electrode 60 from the DC power supply 74. However, it may be also possible to apply a DC voltage from the DC power supply 74 only to the upper electrode 60 or to both of the upper electrode 60 and the focus ring 38.

For example, when etching an SiO₂ film by using a fluorocarbon-based processing gas, a DC voltage of about −900 V may be applied to the upper electrode 60 from the DC power supply 74 via the changeover switch 76 and the DC power supply line 78. At this time, it is desirable not to apply that DC voltage to the focus ring 38. In such case, the thickness of the ion sheath increases extremely on the side of the upper electrode 60, resulting in a downscale of the plasma in an inter-electrode direction. Due to the reduction of the plasma, an effective residence time of the plasma on the semiconductor wafer W can be increased, and since the plasma can be concentrated onto the wafer W while its diffusion is suppressed, dissociation space decreases. As a result, dissociation of the fluorocarbon-based processing gas is suppressed, making it difficult to etch the resist film on the wafer W.

As stated, by connecting the DC power supply 74 to the upper electrode 60 by controlling the changeover switch 76, basic effects or process characteristic effects of an upper-side DC application method can be obtained successfully.

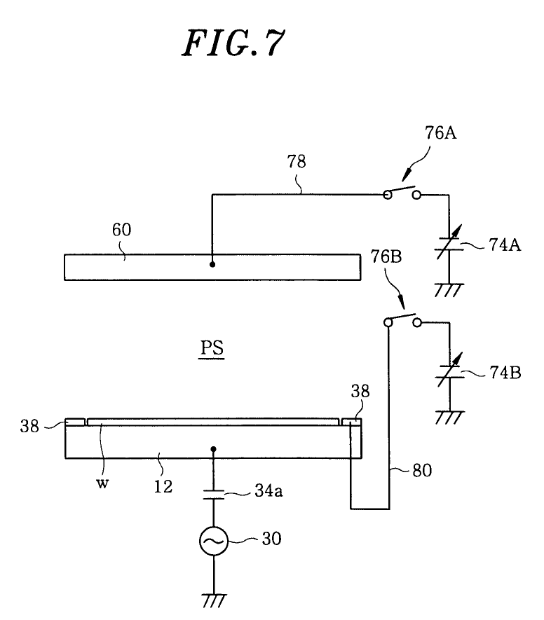

Furthermore, it may be also possible to set up a configuration, as shown in FIG. 7, in which two variable DC power supplies 74A and 74B are provided, and one DC power supply 74A is connected only to the upper electrode 60 via an on/off switch 76A and the DC power supply line 78 while the other DC power supply 74B is connected only to the focus ring 38 via an on/off switch 76B and the DC power supply line 80. By providing dedicated DC voltage supply mechanisms constituted by 74A, 76 and 78 and by 74B, 76B, 80 to the upper electrode 60 and the focus ring 38, respectively, the operation and effect of either one the upper-side DC application method and the focus-ring DC application method in accordance with the present invention can be obtained independently, or the operations and effects of both of them can be obtained simultaneously or organically.

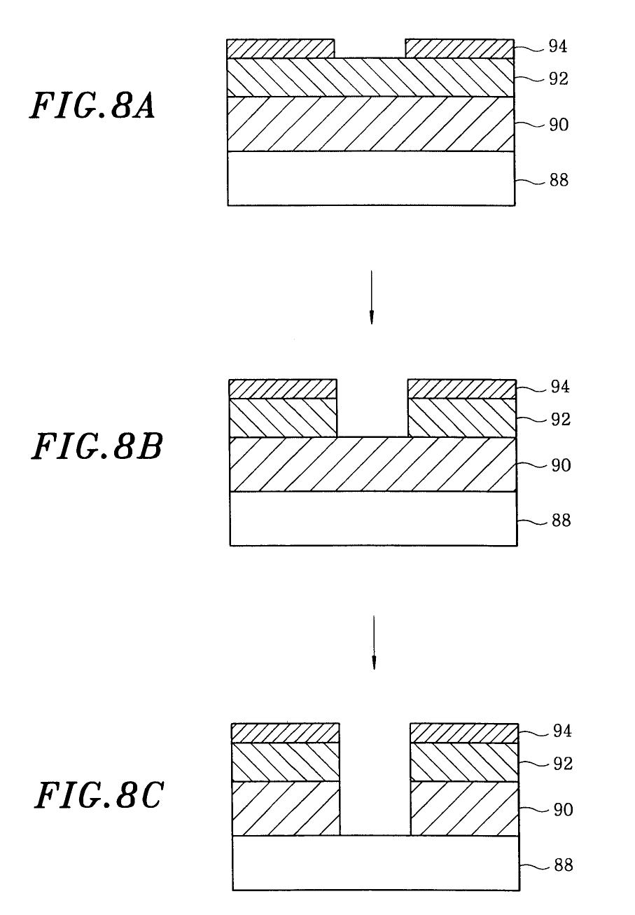

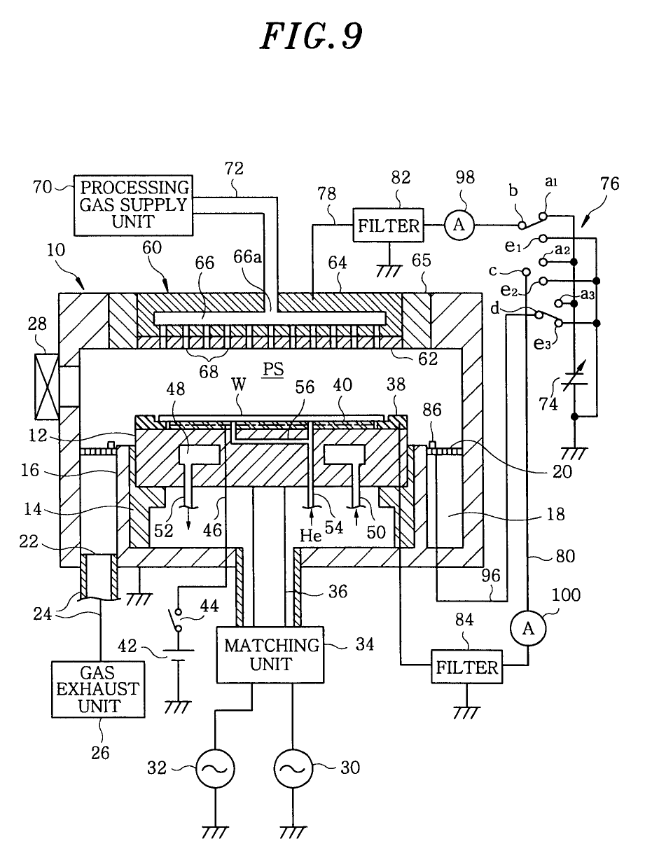

FIGS. 8A to 8C illustrate a typical process for etching an organic film on a semiconductor wafer W by using the plasma etching apparatus (FIG. 1) in accordance with the present embodiment of the present invention. The shown example is a kind of a two-layer resist method, which involves forming, on a processing target film (e.g., an SiO₂ film) 90, an organic film, e.g., a carbon mask 92 as a lower resist by using, e.g., a CVD (Chemical Vapor Deposition) method; forming a resist 94 on the carbon mask 92 by using, e.g., a spin coating method; and forming a pattern on the resist 94 by an exposure/development process (see FIG. 8A). The bottommost film 88 is a base film. During an etching process, the carbon mask 92 is first etched by using the resist 94 as a mask (see FIG. 8B), and then the processing target film 90 is etched by using the resist 94 and the carbon mask 92 as a mask (see FIG. 8C).

At this time, in the first organic film etching process (8B), the focus-ring DC application method as described before with reference to FIGS. 2 to 5 may be employed, whereby the carbon mask 92 on the semiconductor wafer can be etched at a desired etching rate while obtaining in-plane uniformity. Further, in the next SiO₂ etching process (8B), by employing the upper-side DC application method depending on necessity without using the focus-ring DC application method, the SiO₂ film 90 on the semiconductor wafer W can be etched with a desired etching characteristic while obtaining in-plane uniformity.

FIG. 9 illustrates a configuration of a plasma etching apparatus in accordance with a second embodiment of the present invention. In the drawing, parts having the same configurations or functions as those described in the first embodiment are assigned like reference numerals.

The characteristic of the second embodiment pertains to a DC ground component (DC ground electrode) 86.

As described above, if the DC voltage is applied to the focus ring 38 and/or the upper electrode 60, electrons would be accumulated in these members, raising a likelihood that an abnormal discharge may be generated between these members and the chamber sidewall or the like. However, by providing the DC ground component 86 at a proper number of locations exposed to plasma, the electrons accumulated in the focus ring 38 or the upper electrode 60 would arrive at the DC ground component 86 through the plasma and would be discharged from there into a ground line through the chamber sidewall, so that the abnormal discharge can be prevented.

However, if deposits such as polymer generated during the etching process are adhered to the surface of the DC ground component 86, the DC grounding function would be deteriorated, and the effects of the focus-ring DC application method or the upper-side DC application method would be degraded.

In the present embodiment, to reduce or prevent the adherence of the deposits to the DC ground component 86, sputter-cleaning of the DC ground component 86 can be performed in the plasma between etching processes by using an inert gas such as Ar or the like as a cleaning gas.

To elaborate, a changeover switch 76 has three fixed contact points a₁, a₂, and a₃ connected with an output terminal of a variable DC power supply 74; three fixed contact points e₁, e₂, and e₃ connected with a ground terminal; and three movable contact points b, c and d. Here, the movable contact point b is connected with the upper electrode 60 via a DC power supply/ground line 78 and can be switched to be connected either one of the fixed contact points a₁ and e₁. Further, a middle position (floating state) without being connected with any of the fixed points a₁ and e₁ can also be selected. The movable contact point c is connected with the focus ring 38 via a DC power supply/ground line 80, and can be switched to be connected with either one of the fixed contact point a₂ and e₂. A middle position (floating state) without being connected with any of the fixed points a₂ and e₂ can also be selected. The movable contact point d is connected with the DC ground component 86 via a DC power supply/ground line 96 and can be switched to be connected either one of the fixed contact points a₃ and e₃.

When performing the etching process, the movable contact point d is switched to be connected with the fixed contact point e₃, and the DC ground component 86 is grounded through the DC power supply/ground line 96. Meanwhile, the movable contact point c on the side of the focus ring 38 is switched to the fixed contact point a₂ or into the middle position (floating state). The movable contact point b on the side of the upper electrode 60 is switched to either one of the fixed contact point a₁ on the side of the power supply output terminal and the fixed contact point e₁ on the side of the ground terminal or into the middle position (floating state).

When performing the sputter-cleaning of the DC ground component 86, the movable contact point d is switched to be connected with the fixed contact point a₃ on the side of the power supply output terminal, and an output voltage (typically, a negative DC voltage) of the variable DC power supply 74 is applied to the DC ground component 86 via the DC power supply/ground line 96. Meanwhile, at least one of the movable contact points b and c is switched to be connected with the fixed contact point e₁ or e₂ on the side of the ground terminal and at least one of the focus ring 38 and the upper electrode 60 is grounded through the power supply/ground line 80 or 78. As such, by applying the negative DC voltage to the DC ground component 86, a sheath around the DC ground component 86 can be enlarged, and by allowing ions accelerated by an average electric field of the sheath to reach the DC ground component 86, the deposits on the surface of the component 86 can be removed by ion sputtering.

In this second embodiment, current detectors 98 and 100 are installed on the DC power supply/ground lines 78 and 80, respectively. When an appropriate DC voltage is applied to the upper electrode 60 and/or the focus ring 38 from the DC power supply 74 DC, currents flowing through the DC power supply/ground lines 78 and 80 can be measured by the current detectors 98 and 100 by using a Langmuir probe method, and a plasma density, an electron temperature, a plasma potential and the like can be calculated based on the current measurements.

FIG. 10 illustrates a configuration example of a control unit 110 for controlling each component and the entire process sequence of the plasma etching apparatus (FIG. 1 or FIG. 9) to perform the plasma etching apparatus in accordance with the embodiment of the present invention.

The control unit 110 includes a processor (CPU) 152, a memory (Memory) 154, a program storage device (HDD) 156, a disk drive (DRV) 158 such as a floppy disk or an optical disk, an input device (KEY) 160 such as a keyboard or a mouse, a display device (DIS) 162, a network interface (COM) 164 and a peripheral interface (I/F) 166 connected with each other via a bus 150.

The processor (CPU) 152 reads codes of necessary programs from a storage medium 168 such as the FD or the optical disk provided in the disk drive (DRV) 158 and stores them in the HDD 156. Alternatively, it is also possible to download the necessary programs from a network via the network interface (COM) 164. The processor 152 executes each step by developing the codes of the program necessary in each stage or each scene on the working memory RAM 154 from the HDD 156 and controls each component (particularly, the gas exhaust unit 26, the radio frequency power supplies 30 and 32, the processing gas supply unit 70, the variable DC power supply 74, the changeover switch 76, and the like) by performing a required operation process. All the programs necessary to perform the plasma etching method described above are executed by this computer system.

Here, the above description of the present invention is provided for the purpose of illustration, and it should be noted that the present invention is not limited to the embodiments but various changes and modifications may be made. Especially, the configurations of the susceptor 12 and the focus ring 38 can be changed or selected in various ways to be combined with the other components inside the apparatus.

Further, the present invention is not limited to the lower-side dual frequency application type as described in the above embodiments but can be applied to, for example, a lower-side single frequency application type which applies a single frequency power to the susceptor (lower electrode) or a lower-side triple frequency application type which applies triple frequencies to the susceptor (lower electrode). Furthermore, it may be also possible to connect the first radio frequency power supply 30 to the upper electrode 60 and apply the first frequency wave of the preset frequency level, which mainly contributes to plasma generation, to the upper electrode 60.

In the present invention, the target substrate is not limited to the semiconductor wafer, but various other types of substrates such as various flat panel display substrates, a photo mask, a CD substrate, a printed circuit board and the like can be used as well.

While the invention has been shown and described with respect to the embodiments, it will be understood by those skilled in the art that various changes and modifications may be made without departing from the scope of the invention as defined in the following claims.

What is claimed is:

1. A plasma etching apparatus comprising:
a processing vessel which is evacuatable to vacuum;
a lower electrode on which a target substrate is mounted in the processing vessel;
an upper electrode disposed in the processing vessel to face the lower electrode in parallel thereto;
a processing gas supply unit configured to supply a processing gas into a processing space between the upper electrode and the lower electrode;
a first radio frequency power supply unit configured to apply, to the lower electrode, a first radio frequency power for generating plasma of the processing gas by a high frequency discharge;
a focus ring covering a top surface peripheral portion of the lower electrode protruding toward a radial outside of the substrate;
a DC power supply configured to output a variable DC voltage; and
a DC voltage supply network that connects the DC power supply to either one of the focus ring and the upper electrode or both depending on processing conditions of plasma etching.

2. A plasma etching apparatus comprising:
a processing vessel which is evacuatable to vacuum;
a lower electrode on which a target substrate is mounted in the processing vessel;
an upper electrode disposed in the processing vessel to face the lower electrode in parallel thereto;
a processing gas supply unit configured to supply a processing gas into a processing space between the upper electrode and the lower electrode;
a first radio frequency power supply unit configured to apply, to the lower electrode, a first radio frequency power for generating plasma of the processing gas by a high frequency discharge;
a focus ring covering a top surface peripheral portion of the lower electrode protruding toward a radial outside of the substrate,
a first DC power supply configured to output a first variable DC voltage to be applied to the upper electrode;
a second DC power supply configured to output a second variable DC voltage to be applied to the focus ring; and
a DC voltage supply network that connects the first and second DC power supplies to the upper electrode and the focus ring respectively, or connects either one of the first and second power supplies to the upper electrode or the focus ring depending on processing conditions of plasma etching.

3. The plasma etching apparatus of claim 1, further comprising:
a DC ground electrode provided at a position exposed to the plasma in the processing vessel and DC-grounded to flow a DC current between the DC ground electrode and the upper electrode or the focus ring through the plasma.

4. The plasma etching apparatus of claim 2, further comprising:
a DC ground electrode provided at a position exposed to the plasma in the processing vessel and DC-grounded to flow a DC current between the DC ground electrode and the upper electrode or the focus ring through the plasma.

5. A plasma etching apparatus comprising:
a processing vessel which is evacuatable to vacuum;
a lower electrode on which a target substrate is mounted in the processing vessel;
an upper electrode disposed in the processing vessel to face the lower electrode in parallel thereto;
a processing gas supply unit configured to supply a processing gas into a processing space between the upper electrode and the lower electrode;
a first radio frequency power supply unit configured to apply, to the lower electrode, a first radio frequency power for generating plasma of the processing gas by a high frequency discharge;
a focus ring covering a top surface peripheral portion of the lower electrode protruding toward a radial outside of the substrate;
a DC power supply configured to output a variable DC voltage;
a DC ground electrode provided at a position exposed to the plasma in the processing vessel and DC-grounded to flow a DC current between the DC ground electrode and the upper electrode or the focus ring through the plasma;
a DC voltage supply network that connects the DC power supply to either one of the focus ring and the upper electrode or both depending on processing conditions and grounds the DC ground electrode when etching a processing target film on the substrate, and connects the DC power supply with the DC ground electrode and grounds at least one of the upper electrode and the focus ring when sputter-cleaning the surface of the DC ground electrode.

6. The plasma etching apparatus of claim 1, further comprising:
a second radio frequency power supply unit configured to apply a second radio frequency power for attracting ions in the plasma onto the substrate on the lower electrode.

7. The plasma etching apparatus of claim 2, further comprising:
a second radio frequency power supply unit configured to apply a second radio frequency power for attracting ions in the plasma onto the substrate on the lower electrode.

8. The plasma etching apparatus of claim 4, further comprising:
a second radio frequency power supply unit configured to apply a second radio frequency power for attracting ions in the plasma onto the substrate on the lower electrode.

9. A plasma etching method for etching at least an organic film on the substrate by using the plasma etching apparatus of claim 1,
wherein, in a process of etching the organic film, a negative DC voltage having an absolute value larger than that of a self-bias voltage generated on the lower electrode is applied to the focus ring.

10. A plasma etching method for etching at least an organic film on the substrate by using the plasma etching apparatus of claim 2,
wherein, in a process of etching the organic film, a negative DC voltage having an absolute value larger than that of a self-bias voltage generated on the lower electrode is applied to the focus ring.

11. A plasma etching method for etching at least an organic film on the substrate by using the plasma etching apparatus of claim 4,
wherein, in a process of etching the organic film, a negative DC voltage having an absolute value larger than that of a self-bias voltage generated on the lower electrode is applied to the focus ring.

12. The plasma etching method of claim 9, wherein the absolute value of the DC voltage is determined to reduce a difference between an etching rate of a substrate central portion on the substrate and that of a substrate edge portion on the substrate.

13. The plasma etching method of claim 9, wherein the processing gas is free of an inert gas.

14. The plasma etching method of claim 9, wherein the organic film is a carbon film and the processing gas is an O₂ gas.

15. The plasma etching method of claim 9, wherein a processing target film is formed on the substrate in addition to the organic film, and no DC voltage is applied to the focus ring in an etching process of the processing target film.

16. The plasma etching method of claim 9, wherein a specified DC voltage is selectively applied to the upper electrode depending on processing conditions.

17. The plasma etching method of claim 9, wherein a second radio frequency power for attracting ions in plasma onto the substrate is applied to the lower electrode.

18. A computer readable storage medium that stores a computer executable control program, wherein, when executed, the control program controls the plasma etching apparatus to carry out the plasma etching method of claim 9.

19. A computer readable storage medium that stores a computer executable control program, wherein, when executed, the control program controls the plasma etching apparatus to carry out the plasma etching method of claim 10.

20. A computer readable storage medium that stores a computer executable control program, wherein, when executed, the control program controls the plasma etching apparatus to carry out the plasma etching method of claim 11.
